(19) United States
(12) Patent Application Publication
(10) Pub. No.: US 2010/0295067 A1
(43) Pub. Date: Nov. 25, 2010

(54) LIGHT EMITTING DEVICE WITH COLLIMATING STRUCTURE

(75) Inventors: Michel Cornelis Josephus Marie Vissenberg, Eindhoven (NL); Ramon Pascal Van Gorkom, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/445,758

(22) PCT Filed: Oct. 15, 2007
(86) PCT No.: PCT/IB07/54179

§ 371 Date: Apr. 16, 2009

(30) Foreign Application Priority Data
Oct. 20, 2006 (EP) 06122635.3

(51) Int. Cl. H01L 33/58; G02B 27/30

(52) U.S. Cl. 257/89; 359/641; 257/E33.068

(57) ABSTRACT

The present invention provides a light collimating structure (102) comprising a first collimator (131) collimating light of a first property and at least one second collimator (141) collimating light of a second property, where the receiving areas (132, 142) of the collimators at least partly overlap and where the output areas (133, 143) of the collimators partly overlap. The at least two collimators act essentially independently from each other. Hence, the collimators can be positioned independently from each other, in order to provide good collimation for each of the light sources of the lighting unit. Further, the collimators may be designed independently from each other such that a good light mixing is obtained.

### FIELD OF THE INVENTION

The present invention relates to a light collimating structure, as well as to a light-emitting device comprising a lighting unit with such a light collimating structure arranged to receive and collimate light emitted by the lighting unit.

### BACKGROUND OF THE INVENTION

Recently, much progress has been made in increasing the brightness of light emitting diodes (LEDs). As a result, it is anticipated that LEDs, in the coming years, will become sufficiently bright and inexpensive to serve as light sources in lamps with adjustable color, backlights for liquid crystal displays, front and rear projection displays and projectors that generate light patterns.

For many of these applications, it is desired that the light sources emit collimated light, where the beam shape and color can be set. Furthermore, the colors should be well mixed.

Color variability is conventionally obtained by grouping several LEDs of different colors into one lighting unit, a pixel. By independently addressing the different LEDs in such a lighting unit, the intensity of light emitted by each of the LEDs can be controlled and varied, such that the total color there from can be set.

Color mixing and collimation can be obtained by placing the LEDs of the lighting unit close together at the entrance of a collimator.

However, since the LEDs are positioned in different positions in respect to the collimator, the color mixing is far from perfect, and the position of the LEDs in the collimator will lead to noticeable differently colored regions in the far field spot.

An approach to improve the color mixing is described in US patent application no 2006/0001034 A1, describing a RGB (red, green, blue) LED package arranged at the bottom of a collimating funnel. The collimating funnel is filled with a photo mixing, light scattering material uniformly dispersed in a filler-resin that fills the collimating funnel. The photo mixing material serves to improve the color mixing of light exiting the funnel.

However, the photo mixing material will reduce the light utilization efficiency, since it will prevent at least part of the light emitted from exiting the funnel, by means of for example absorption of light and reflection back towards the LEDs.

Further, the scattering material in the collimating funnel, especially close to the output opening, will negatively affect the collimation obtainable by the device.

Hence, there is a need in the art for a light collimating structure that can collimate light from several LEDs arranged side by side, and which can provide good color mixing, without the need for a color mixing and light scattering material filling the collimator.

### SUMMARY OF THE INVENTION

One object of the present invention is to at least partly overcome this problem, and to provide a collimating device that can collimate light from a multi-LED lighting unit and that provides a good color mixing of the collimated light.

It is another object of the present invention to provide a light-emitting device comprising a multi-light source lighting unit and such a collimator.

Thus, in a first aspect, the present invention relates to a light collimating structure, comprising at least a first and a second funnel-shaped collimator. Each of the collimators has a receiving area and an output area, where the receiving area is smaller than the output area, and sidewalls connecting the receiving area with the output area. The receiving area of said first collimator and the receiving area of said second collimator form an overlapping region, through which region light may be received into said collimating structure. The output area of said first collimator and the output area of said second collimator are partly overlapping.

The sidewalls of said first collimator are reflective for light of a first property, and the sidewalls of said second collimator are reflective for light of a second property. Further, portions of the sidewalls of said first collimator, which portions are located in the path of light between said overlapping region and the sidewalls of said second collimator, are transmissive for light of said second property. Likewise, portions of the sidewalls of said second collimator, which portions are located in the path of light between said overlapping region and the sidewalls of said first collimator, are transmissive for light of said first property.

In a second aspect, the present invention relates to a light emitting device comprising at least a lighting unit and a collimating structure according to the present invention arranged to receive and collimate light emitted by said lighting unit. The lighting unit comprises at least a first light source for emitting light of a first property and a second light source for emitting light of a second property, and the light emitted by said lighting unit is received into said collimating structure through said overlapping region of the receiving areas of the collimating structure.

In a light-emitting device of the present invention, the light from all light sources in a lighting unit is collimated in the same collimating structure. Thus, the light-emitting device may be of a relatively compact design.

The light from all the light sources of a lighting unit enters the collimating structure via a shared overlapping region of the receiving areas. Thus, the light sources can be located close to one another, allowing a compact design and obviating the need for a separate receiving area in each collimator.

The light from the first light source is collimated by the first collimator and the light from the second light source is collimated by the second collimator. The collimators thus act essentially independently from each other. Hence, the collimators can be positioned independently from each other, in order to provide good collimation for each of the light sources of the lighting unit. Further, the collimators may be designed independently from each other such that a good light mixing is obtained.

The first light property may be a first wavelength interval or a first polarization state, and the second light property may be a second wavelength interval or a second polarization state. Hence, a collimating device of the present invention may be used to collimate and mix light of different wavelength intervals or of different polarization states.

The device of the present invention may be used to collimate and mix light of different wavelength intervals, e.g. different colors, or of different polarization states.

In embodiments of the present invention, the portions of the sidewalls of said first collimator, which are transmissive for light of said second property may be provided with a filter which is reflective for light of said property and transmissive for light of said second property. Likewise, the portions of the sidewalls of said second collimator, which are transmissive for light of said first property, may be provided with a filter which is reflective for light of said second property and transmissive for light of said first property. The possibility of arranging filters to handle the selective transmission and reflection gives a freedom in designing the collimating structure, since the filters can be arranged on any material forming the sidewalls of the collimator, or may even constitute the material forming the sidewalls of the collimator.

To obtain the selective reflection and the selective transmission, the portions of the sidewalls are provided with, typically coated with, or consisting of, a filter material having the desired properties.

The filter with selective reflection and transmission properties may comprise a stack of alternating layers having different refractive index and/or different thickness.

Such filters, based on interference stacks, are very well suited as the selectively transmissive and selectively reflective filters as they easily can be adapted to selectively reflect and transmit light of different wavelengths, and have a very low absorption for the wavelengths of interest.

In embodiments of the present invention, the angle between the surface of the sidewalls of the first and/or the second collimator and the normal to the substrate decreases with the distance from said substrate.

When the sidewalls of the collimators are curved in this manner, forming a concave inner surface of the collimator, the height of the collimator can be reduced in order to obtain the same degree of collimation, compared to a collimator having straight sidewalls.

In embodiments of the present invention, the light collimating structure may further comprise a pre-collimator having a receiving area and an output area, being arranged such that said output area of said pre-collimator faces said receiving areas of said first and second collimators.

By arranging a pre-collimator at the receiving side of the light collimating structure, the light entering the at least one of first and second collimators is collimated to a certain extent. Also, such a light collimating structure may be easy to manufacture.

In embodiments of the present invention, the light collimating structure may further comprise a post-collimator having a receiving area and an output area, being arranged such that said receiving area of said post-collimator faces said output areas of said first and second collimators.

By arranging a post collimator at the output side of the light collimating structure, the output light may be further collimated.

In embodiments of the present invention, the said first light source may comprise a first light emitting diode, and the second light source may comprise a second light emitting diode. The first light emitting diode and the second light emitting diode may be arranged side-by-side on a substrate.

The proposed collimation structure is well suited for collimating and mixing light from light emitting diodes. Light emitting diodes typically emit light in a half-sphere pattern, and collimation of the light is often desired.

Especially, the proposed collimation structure is well suited for collimating light from densely packed light emitting diodes, such as the separate diodes of a multiLED-package, due to that light of each color is collimated essentially independently from the other colors, even though light from all LEDs enter the collimating structure through the same overlapping region.

In embodiments of the present invention, output area of said first collimator may be arranged centrally in front of said first light source, and/or the output area of said second collimator may be arranged centrally in front of said second light source.

In embodiments of the present invention, the receiving area of said first collimator may be arranged centrally in front of said first light source, and/or the receiving area of said second collimator may be arranged centrally in front of said second light source.

### BRIEF DESCRIPTION OF THE DRAWINGS

This and other aspects and advantages of the present invention will now be described more in detail, with reference to the appended drawings showing embodiments of the invention.

FIG. 1 illustrates, in cross-sectional side view, an embodiment of the preset invention.

FIG. 2 illustrates, in cross-section side view, another embodiment of the present invention.

FIG. 3 illustrates in perspective top view, yet another embodiment of the present invention.

FIG. 4 illustrates in top view, the embodiment of FIG. 3.

FIG. 5 illustrates, in cross-section side view, yet another embodiment of the present invention.

FIG. 6 illustrates, in cross-section side view, yet another embodiment of the present invention.

### DETAILED DESCRIPTION OF PREFERRED EMBODIMENTS

The present invention relates in part to a light emitting device comprising a lighting unit and a collimating structure arranged to receive and collimate the light emitted by the lighting unit. The collimating structure it self forms an especially contemplated aspect of the present invention, even though it is herein below described as a component of a light emitting device.

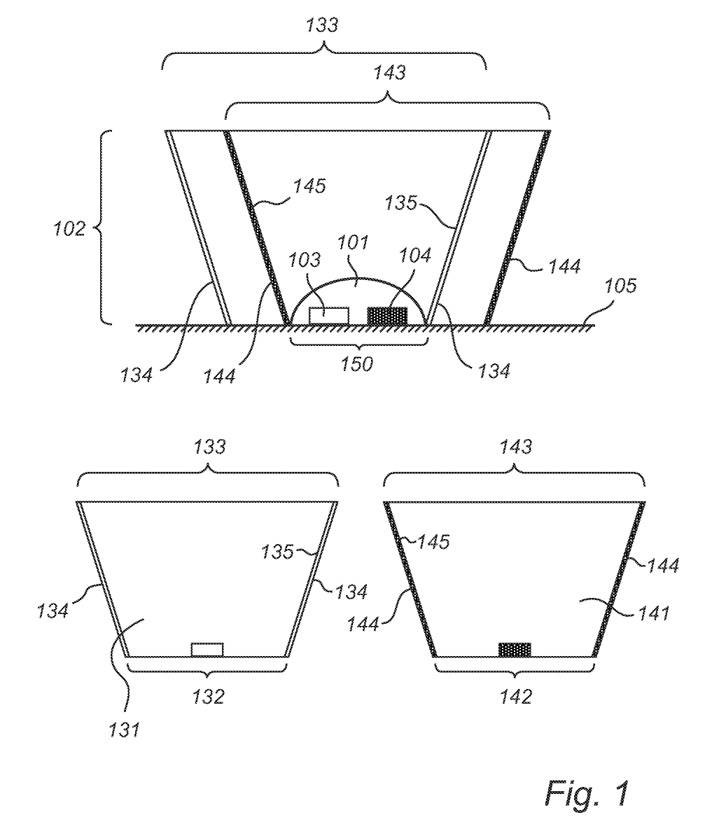

A first exemplary embodiment of a light-emitting device of the present invention is illustrated in cross-sectional view in FIG. 1.

The light-emitting device comprises a lighting unit 101 on which a light collimating structure 102 is arranged.

The lighting unit 101 comprises a first light emitting diode (LED) 103 capable of emitting light of a first wavelength interval, e.g. light of a first color, and a second light emitting diode 104 capable of emitting light of a second wavelength interval, e.g. light of a second color.

As used herein, “light-emitting diodes” relates to all different types of light emitting diodes (LEDs), including organic based LEDs, polymeric based LEDs and inorganic based LEDs, which in operating mode emits light of any wavelength or wavelength interval, from ultra violet to infrared. Light emitting diodes, in the context of this application, are also taken to encompass laser diodes, i.e. light emitting diodes emitting laser light.

The light emitting diodes 103, 104 are arranged side by side on a substrate 105 to form a multi-LED package.

The LEDs are arranged to emit light in a main direction along the normal of the substrate 105.

The light collimating structure 102 is arranged in front of the LEDs 103, 104, counted in the main direction of light emitted by the LEDs, in order to receive and collimate at least part of the light emitted.

The light collimating structure 102 comprises a first collimator 131, which is adapted to collimate light emitted by the first light emitting diode 103, i.e. light of the first wavelength interval, and a second collimator 141, which is adapted to collimate light emitted by the second light emitting diode 104, i.e. light of the second wavelength interval.

As used herein, the term “collimator” refers to an optical element that is capable of receiving electromagnetic (EM) radiation, e.g. light in the interval from UV to IR, and reduces the angular spread angle of the received EM-radiation

Each of the collimators 131, 141 comprises a receiving area 132, 142, facing the lighting unit 101, through which light emitted by the lighting unit enters the collimator, and an output area 133, 143, through which light exits the collimator.

The collimators are funnel-shaped, such that the receiving area 132, 142 is smaller than the respective output area 133, 143, and the collimators comprise sidewalls 134, 144, which are reflective of the light to be collimated. Due to the funnel shape of the collimators, the angular spread of light exiting the collimators will be smaller than the angular spread of light received into the collimators.

The sidewalls 134 of the first collimator 131 are reflective for the light emitted by the first light emitting diode 103, i.e. light of the first wavelength interval. Likewise, the sidewalls 144 of the second collimator 141 are reflective for light emitted by the second light emitting diode 104, i.e. light of the second wavelength interval.

The sidewalls 134, 144 of the collimators are arranged such that the receiving area 132 of the first collimator 131 and the receiving area 142 of the second collimator 141 form an overlapping region 150. The collimating structure 102 is positioned in front of the lighting unit 101 such that the light emitted by both the first light emitting diode 103 and the light emitted by the second light emitting diode 104 is transmitted into the collimating structure 102 through this overlapping region 150.

Further, the receiving area 132 of the first collimator 131 is located centrally in front of first light emitting diode 103, i.e. the first light emitting diode 103 is arranged in rear of the central point of the receiving area. Likewise, the receiving area 142 of the second collimator 141 is located centrally in front of the second light emitting diode 104.

The sidewalls are further arranged such that also the output area 133 of the first collimator 131 and the output area 143 of the second collimator 141 overlap, and so that the lateral distance between the center points of the output areas equals the lateral distance between the center points of the receiving areas.

The shape of the first collimator 131 and the second collimator 141 is essentially the same, both having the shape of a funnel that is symmetrical in respect to the normal of the receiving area.

The first collimator 131 is thus partly arranged within the second collimator 141, and vice versa. Thus, portions 135 of the sidewalls 134 of the first collimator 131 are positioned in the light path between the second light emitting diode 104 and the sidewalls 144 of the second collimator. Likewise, portions 145 of the sidewalls 144 of the second collimator 141 are positioned in the light path between the first light emitting diode 103 and the sidewalls 134 of the first collimator.

The portions 135 of the first collimator 131 that are located in the second collimator 141 are constituted by a filter that is transmissive for light emitted by the second light emitting diode 104, but are reflective for light emitted by the first light emitting diode 103. Thus, light from the second light emitting diode 104 will be transmitted essentially unaffected through that portion 135 of the sidewall of the first collimator.

Likewise, the portions 145 of the second collimator 141 that are located in the first collimator 131 are constituted by a filter that is transmissive for light emitted by the first light emitting diode 103, but are reflective for light emitted by the second light emitting diode 104. Thus, light from the first light emitting diode 103 will be transmitted essentially unaffected through that portion 145 of the sidewalls of the second collimator.

To sum up, light from the first light emitting diode 103 will be collimated by being reflected on the sidewalls 134 of the first collimator 131, and light from the second light emitting diode 104 will be collimated by being reflected on the sidewalls 144 of the second collimator 141, even though the first collimator is partly located within the second collimator, and vice versa.

Since in this embodiment, both collimators thus have the same shape, and since each of the light emitting diodes are located in the center of their respective collimator, the light exiting the first collimator should have the same main direction and angular spread as the light exiting the second collimator. There will only be a small lateral shift corresponding to the distance between the first and the second LED.

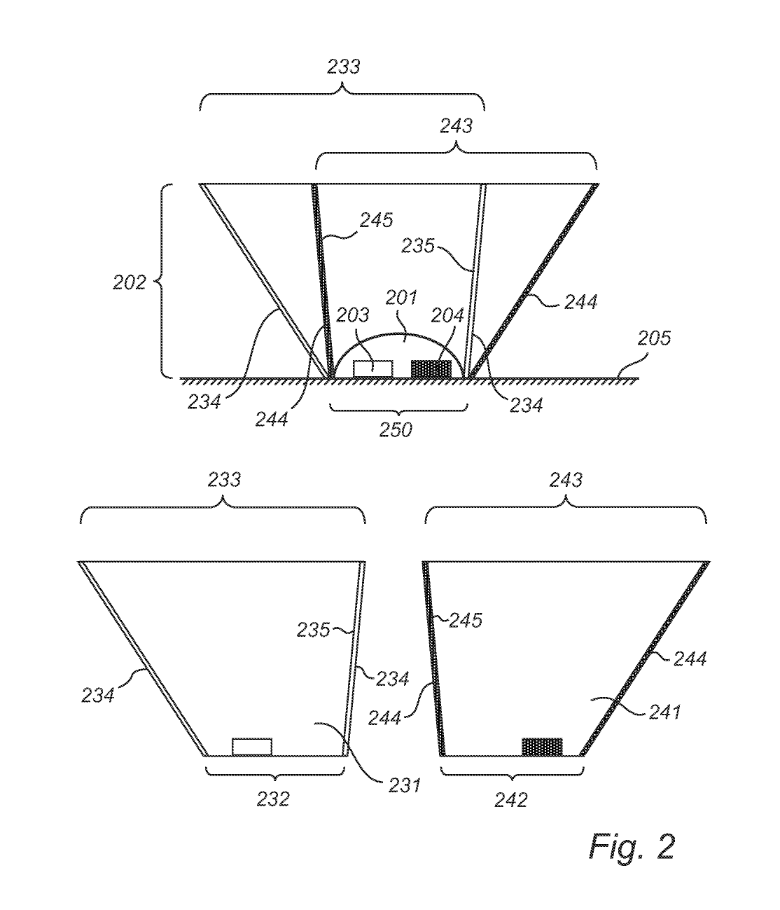

A second embodiment of the present invention is illustrated in FIG. 2. In this embodiment, the difference to the first embodiment is the shape of the collimating structure 202. The lighting unit 201 is as described above for the first embodiment.

The collimating structure 202 comprises a first collimator 231, which is adapted to collimate light emitted by the first light emitting diode 203, i.e. light of the first wavelength interval, and a second collimator 241, which is adapted to collimate light emitted by the second light emitting diode 204, i.e. light of the second wavelength interval.

Each of the collimators 231, 241 comprises a receiving area 232, 242, facing the lighting unit 201, through which light emitted by the lighting unit enters the collimator, and an output area 233, 243, through which light exits the collimator.

The collimators are funnel-shaped, such that the receiving area 232, 242 is smaller than the respective output area 233, 243, and the collimators comprise sidewalls 234, 244, which are reflective of the light to be collimated.

The sidewalls 234 of the first collimator 231 are reflective for the light emitted by the first light emitting diode 203. Likewise, the sidewalls 244 of the second collimator 241 are reflective for light emitted by the second light emitting diode 104.

The sidewalls 234, 244 of the collimators are arranged such that the receiving area 232 of the first collimator 231 and the receiving area 242 of the second collimator 241 essentially fully overlap, forming an overlapping region 250. The collimating structure 202 is positioned in front of the lighting unit 201 such that the light emitted by both the first light emitting diode 203 and the light emitted by the second light emitting diode 204 is transmitted into the collimating structure 202 through this overlapping region 250.

Because of the full overlap, the receiving area 232 of the first collimator 231 is not centrally located in front of the first LED 203, and the receiving area 242 of the second collimator 242 is not centrally located in front of the second LED 204.

The sidewalls 234, 244 are further arranged that also the output area 233 of the first collimator 231 and the output area 243 of the second collimator 241 overlaps. However, here the lateral distance between the center points of the output areas is larger than the lateral distance between the center points of the receiving areas, since that distance is zero.

As a result, the collimators 231, 241 are not symmetrical with respect to the normal of the substrate 205.

The first light emitting diode 203 is positioned on one (here left) side of the center of the overlapping portion 250, and the second light emitting diode 204 is positioned on the opposite (here right) side of the center of the overlapping portion.

Further, the centerline of the first collimator 231 is tilted towards the first light emitting diode 203, and the centerline of the second collimator 241 is tilted towards the second light emitting diode 204.

As a result, even though the light emitting diodes 203, 204 are not placed in the center of their respective collimators, by choosing the tilt angle of the center lines properly, the main direction of light exiting the collimators 231, 241 is along the normal of the substrate 205, and the angular spread of light emanating from the first LED 103 is essentially equal to the angular spread of light emanating from the second LED.

One advantage of this second embodiment over the first embodiment described above is that due to the total overlap of the receiving areas, the total receiving area (i.e. receiving area of the first collimator+the receiving area of the second collimator−the overlapping portion) can be made smaller in the second embodiment than in the first embodiment. Thus, the first embodiment exhibits a loss of etendue when compared to the second embodiment.

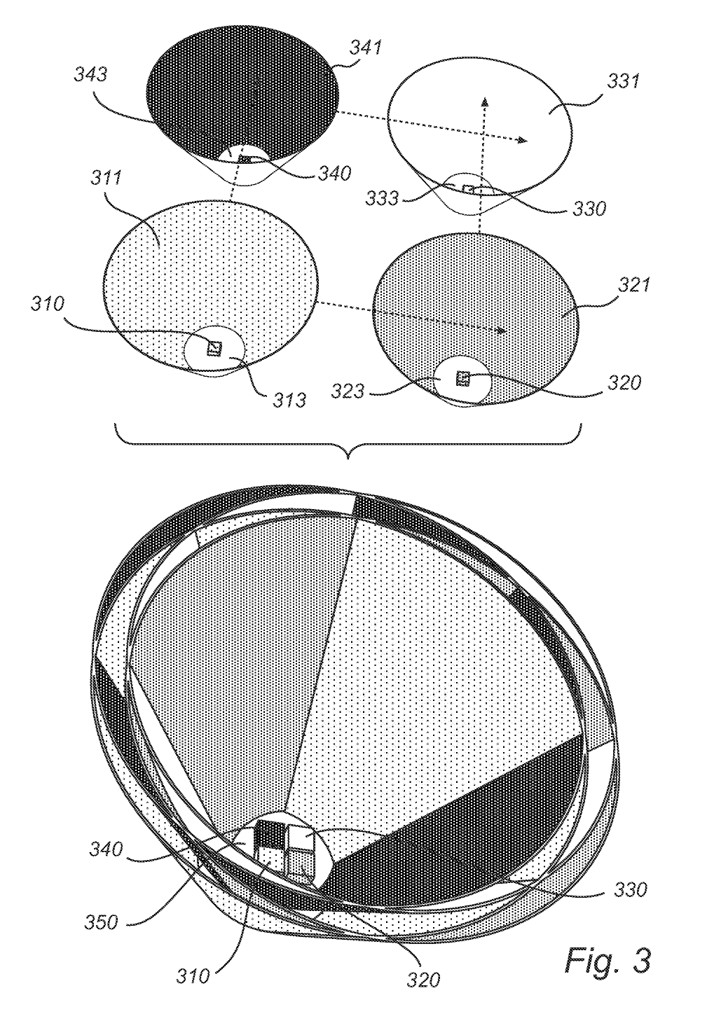

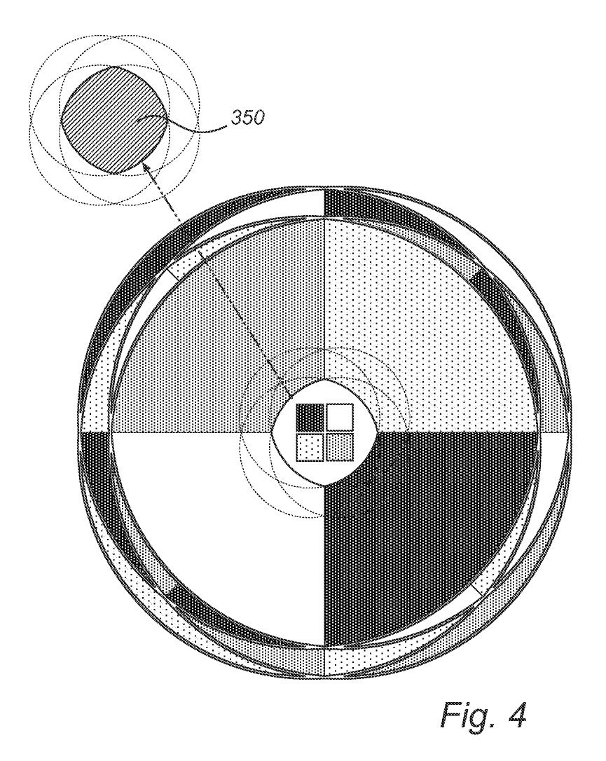

A third exemplary embodiment of the present invention is illustrated in FIG. 3, showing a top view cross section of a light-emitting device according to the present invention.

The light emitting device comprises a lighting unit comprising a first LED 310, a second LED 320, a third LED 330 and a fourth LED 340 arranged on a substrate (not shown), and a collimating structure arranged to receive and collimate light from the lighting unit.

The collimating structure comprises a first collimator 311 for collimation of the light emitted by the first LED 310, a second collimator 321 for collimation of the light emitted by the second LED 320, a third collimator 331 for collimation of the light emitted by the third LED 330, and a fourth collimator 341 for collimation of the light emitted by the fourth LED 310.

Each of the collimators 311, 321, 331, 341 are funnel shaped with a receiving area being smaller than the output area, and sidewalls connecting the receiving area with the output area. The sidewalls of the collimators are reflective for light from its corresponding light emitting diode. In top view, the cross-section of the collimators is circular.

The collimators 311, 321, 331, 341 are partly located within each such that the receiving areas 313, 323, 333, 343 form an overlapping region 350. The light from all four LEDs 310, 320, 330, 340 enters their respective collimator through a portion of the receiving area being part of this overlapping region 350.

Further, each of the collimators is arranged such that its receiving area is centrally arranged in front of its corresponding LED.

As in the above embodiments, portions of the sidewalls of a collimator that are located within another collimator (i.e. located in the light path between the overlapping region 350 and the sidewalls of that other collimator) are transmissive, typically by means of a dichroic filter, for light from the light emitting diode corresponding to that other collimator. Hence, portions of the sidewalls of the first collimator 311 that are located within the second collimator 321 are transmissive for light from the second LED 320, portions located within the third collimator 331 are transmissive for light from the third LED 330, and portions located within the fourth collimator 341 are transmissive for light from the fourth LED 340. An analogue reasoning holds for the sidewalls of the second, third and fourth collimators.

In an alternative (not shown) to this third embodiment, the receiving areas of the first, second, third and fourth collimators fully overlap, such that the overlapping region, through which light is received into the collimators is constituted by the full area of the four receiving areas of the four collimators. Further, also in this alternative, the output areas of the first, second, third and fourth collimators partly, but not fully overlap.

Filters that are transmissive for light of one wavelength interval and reflective for another wavelength interval are known to those skilled in the art, for example under the collective term dichroic filters. As used herein, the term “dichroic filter” relates to a filter that reflects electromagnetic radiation of one or more wavelengths or wavelength ranges, and transmits wavelengths or wavelength ranges, while maintaining a low, typically nearly zero, coefficient of absorption for all wavelengths of interest.

As used herein, the term “wavelength interval” refers to both continuous and discontinuous wavelength intervals.

A dichroic filter may be of high-pass, low-pass, band-pass or band rejection type.

Examples include so-called interference stacks. An interference stack is a multi-layer stack containing alternating layers of material having different refractive index and/or thickness.

One example of an interference stack comprises alternating layers of Ta₂O₅ and SiO₂, where the thickness of each layer is typically approximately equal to a quarter of the wavelength in air divided with the index of refraction, where the wavelength in air equals the dominant wavelength of the light that the dichroic filter reflects.

Other examples of dichroic filters known to those skilled in the art and suitable for use in the present invention are such filters based on cholesteric liquid crystals, so called photonic crystals or holographic layers.

Further, the filters may be non-ideal, i.e. not reflecting 100% of the light in the wavelength range in which the filter is to reflect light and/or not transmitting 100% of the light the wavelength range in which the filter is to transmit light. Thus, the term “filter reflective for light of a first wavelength interval and transmissive for light of a second wavelength interval” is to be taken as “filter that at least partially reflect light of a first wavelength interval and that at least partly transmits light of a second wavelength interval”.

Further, such a filter may be designed to reflect light of two wavelength intervals while transmitting a third wavelength interval, for example, reflecting red and green light while transmitting blue light.

Typically, the filter is arranged as a coating on the sidewalls.

The sidewalls of the collimators, that are reflective for light of at least one wavelength interval, may be constituted by self supporting wall elements, interfaces between two solid bodies or the interface between a solid body and the surrounding atmosphere.

In the figures to the embodiments described above, the sidewalls of the collimators are illustrated as being straight, in the sense that the angle between the surface of the sidewalls and the normal to the substrate is constant, independently on the distance from the substrate.

However, the present invention is not limited to this. In fact, it may be advantageous in some cases that the angle between the surface of the sidewalls and the normal to the substrate is varying, and especially decreasing, with the distance from the substrate. For example, the sidewalls of the collimators may be curved such that the cross-section of the collimator resembles that of a parabola. One such example is the collimator shape commonly known as compound parabolic collimator. For such a collimator shape, the height of the collimator may be reduced, compared to a straight wall collimator, in order to obtain the same degree of collimation.

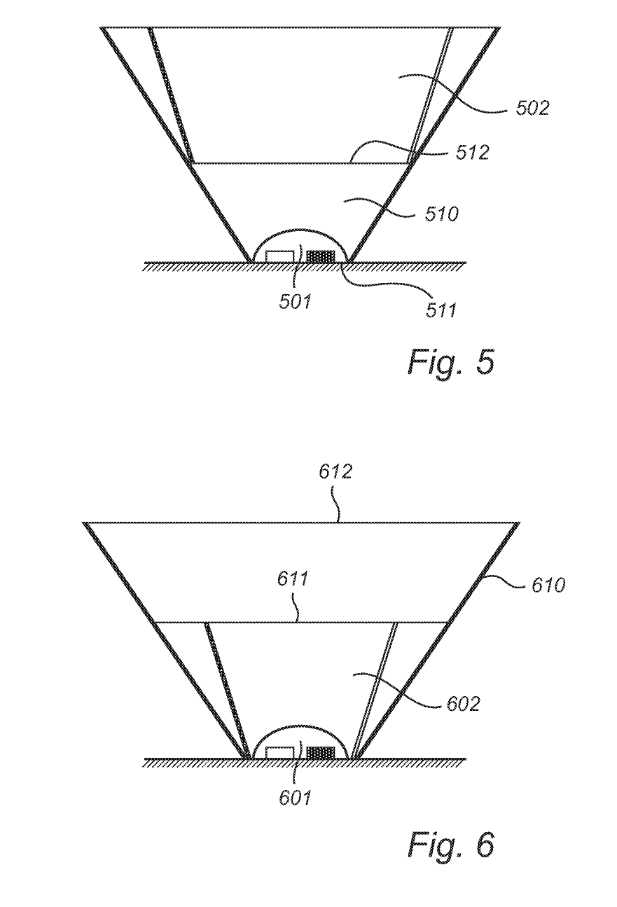

In embodiments of the invention, as is illustrated in FIG. 5, a pre-collimator 510 is arranged between a lighting unit 501 and a collimating structure 502, such that the light entering the collimating structure 502 of the invention is already collimated to a certain extent by the pre-collimator. The collimating structure may be any collimating structure according to the present invention, such as described above.

The pre-collimator 510 is typically a funnel-shaped collimator having a receiving area 511 and an output area 512. In a light-emitting device of the present invention, the receiving area 511 of the pre-collimator is arranged to receive light emitted by the lighting unit 501.

The output area 512 of the pre-collimator 510 faces the receiving areas of the collimators of the collimating structure 502, typically the overlapping region of the collimators of the collimating structure. The sidewalls of the pre-collimator are preferably reflective for the light from all the light sources in the lighting unit.

The pre-collimator 510 and the collimating structure 502 may be formed as separate articles or may be a single article.

In embodiments of the invention, as is illustrated in FIG. 6, a post-collimator 610 is arranged on the output side of the collimating structure 602 of the present invention, such that the light exiting the collimating structure 602 is further collimated by the post-collimator 610. The collimating structure may be any collimating structure according to the present invention, such as described above.

The post-collimator 610 is typically a funnel-shaped collimator with a receiving area 611 and an output area 612.

The receiving area 611 of the post-collimator 610 faces the output areas of the collimators in the collimating structure 602. The sidewalls of the post-collimator are preferably reflective for the light from all the light sources in the lighting unit.

The post-collimator 610 and the collimating structure 602 may be formed as separate articles or may be a single article.

The person skilled in the art realizes that the present invention by no means is limited to the preferred embodiments described above. On the contrary, many modifications and variations are possible within the scope of the appended claims. For example, even though the above embodiments uses light emitting diodes as light sources, any other light source may be utilized in the lighting unit, such as for example fluorescent tubes, incandescent bulbs and discharge lamps.

The collimating structure of the present invention may not only be used to collimate and mix light of different wavelength intervals, or colors. The collimating structure may alternatively be used to collimate and mix light of two or more different polarization states. Thus, in appropriate passages of the description herein, the term “wavelength interval” may be substituted by “polarization state”, “dichroic filter” may be substituted by “polarization filter” and “color” may be substituted by “polarization”.

The present invention is not limited to two or four collimators forming a collimating structure. As will be realized by those skilled in the art, the present invention is also valid for embodiments with three or more collimators forming the collimating structure.

Those skilled in the art will realize that certain portions of the sidewalls of a collimator are not located within any other collimator. Such portions, typically forming the outer boundaries of the collimating structure, may thus be made reflective for light of any wavelength, since there in some cases is no additional effect in such portions being selectively reflective for light of a certain wavelength interval. This is exemplified in FIGS. 5 and 6, where the outmost sidewalls of the collimators are capable of reflecting light of all wavelengths emitted by the light source.

Finally, the structure may be simplified by combining close-by color filter walls into one that reflects two or more colors of light, and/or by leaving out part of the color filter structure. This way, the color filter structures may become easier to manufacture, while a partial correction of the color asymmetry can still be obtained. For example, in FIG. 3 only the four innermost segments and the four outermost segments may be applied, leaving out the sidewalls in between. This simplifies construction considerably, while a significant improvement in color uniformity is still reached.

1. A light collimating structure (102), comprising a first collimator (131) and at least one second collimator (141), wherein:
each of said collimators (131, 141) is funnel-shaped and has a receiving area (132, 142) and an output area (133, 143) where the receiving area is smaller than the output area, and sidewalls (134, 144) connecting the receiving area (132, 142) with the output area (133, 143);
the receiving area (132) of said first collimator (131) and the receiving area (142) of said second collimator (141) form an overlapping region (150), through which region light may be received into said collimating structure (102);
the output area (133) of said first collimator (131) and the output area (143) of said second collimator (141) partly overlaps;
the sidewalls (134) of said first collimator (131) are reflective for light of a first property, and the sidewalls (144) of said second collimator (141) are reflective for light of a second property;
portions (135) of the sidewalls (134) of said first collimator (131), which are located in the path of light between said overlapping region (150) and the sidewalls (144) of said second collimator (141), are transmissive for light of said second property; and
portions (145) of the sidewalls (144) of said second collimator (141), which are located in the path of light between said overlapping region (150) and the sidewalls (134) of said first collimator (131), are transmissive for light of said first property.

2. A light collimating structure according to claim 1, wherein said first light property is first wavelength interval, and said second light property is a second wavelength interval.

3. A light collimating structure according to claim 1, wherein said portions (135) of the sidewalls (134) of said first collimator (131), which are transmissive for light of said second property (104) are provided with a filter which is reflective for light of said property (103) and transmissive for light of said second property (104).

4. A light collimating structure according to claim 1, wherein said portions (145) of the sidewalls (144) of said second collimator (141), which are transmissive for light of said first property are provided with a filter which is reflective for light of said second property and transmissive for light of said first property.

5. A light collimating structure according to claim 3, wherein said filter comprises a stack of alternating layers having different refractive index and/or different thickness.

6. A light collimating structure according to claim 1, wherein the angle between the surface of the sidewalls (134, 144) of the first and/or the second collimator (131, 141) and the normal to the substrate (105) decreases with the distance from said substrate.

7. A light collimating structure according to claim 1, further comprising a pre-collimator (510) having a receiving area (511) and an output area (512), being arranged such that said output area (512) of said pre-collimator faces said receiving areas of said first and second collimators.

8. A light collimating structure according to claim 1, further comprising a post-collimator (610) having a receiving area (611) and an output area (603), being arranged such that said receiving area (602) of said post-collimator faces said output areas of said first and second collimators.

9. A light emitting device, comprising at least a lighting unit (101) and a collimating structure (102) according to claim 1, arranged to receive and collimate light emitted by said lighting unit (101), wherein
said lighting unit (101) comprises at least a first light source (103) for emitting light of a first property and a second light source (104) for emitting light of a second property, and
the light emitted by said lighting unit (101) is received into said collimating structure through said overlapping region (150) of said collimating structure.

10. A light emitting device according to claim 9, wherein said first light source (103) emits light of a first wavelength interval and wherein said second light source (104) emits light of a second wavelength interval.

11. A light emitting device according to claim 9, wherein said first light source (103) comprises a first light emitting diode, and wherein said second light source (104) comprises a second light emitting diode.

12. A light emitting device according to claim 11, wherein said first light emitting diode (103) and said second light emitting diode (104) are arranged side-by-side on a substrate.

13. A light emitting device according to claim 9, wherein the output area (133) of said first collimator (131) is arranged centrally in front of said first light source (103), and/or wherein the output area (143) of said second collimator (141) is arranged centrally in front of said second light source (104).

14. A light emitting device according to claim 9, wherein the receiving area (132) of said first collimator (131) is arranged centrally in front of said first light source (103), and/or wherein the receiving area (142) of said second collimator (141) is arranged centrally in front of said second light source (104).
